(19) United States
(12) Patent Application Publication
(10) Pub. No.: US 2014/0361437 A1
(43) Pub. Date: Dec. 11, 2014

(54) PACKAGE SUBSTRATES AND METHODS OF FABRICATING THE SAME

(71) Applicant: SK hynix Inc., Icheon-si Gyonggi-do (KR)

(72) Inventors: Hyun Chul SEO, Icheon-si Gyeonggi-do (KR); Jong Hoon KIM, Suwon-si Gyeonggi-do (KR); Jae Woong YU, Hwaseong-si Gyeonggi-do (KR)

(73) Assignee: SK hynix Inc., Icheon-si Gyeonggi-do (KR)

(21) Appl. No.: 14/082,289

(22) Filed: Nov. 18, 2013

(30) Foreign Application Priority Data
Jun. 11, 2013 (KR) 10-2013-0066494

(51) Int. Cl. H01L 23/48; H01L 21/768

(52) U.S. Cl. CPC H01L 23/48; H01L 21/768
USPC 257/773; 438/666

(57) ABSTRACT

Package substrates are provided. The package substrate includes a core layer having a first surface defining trench portions and ridge portions between the trench portions, at least one first trace on a bottom surface of each of the trench portions, and second traces on respective ones of top surfaces of the ridge portions. Related methods are also provided.

### CROSS-REFERENCE TO RELATED APPLICATION

The present application claims priority under 35 U.S.C 119(a) to Korean Application No. 10-2013-0066494, filed on Jun. 11, 2013, in the Korean intellectual property Office, which is incorporated by reference herein in its entirety as set forth in full.

### BACKGROUND

1. Field of Invention

Embodiments of the present disclosure relate to electronic device packages and, more particularly, to package substrates and methods of fabricating the same.

2. Description of the Related Art

Electronic devices employed in electronic systems may include various electronic circuit elements and the electronic circuit elements may be integrated in and/or on a semiconductor substrate to constitute the electronic devices (also, referred to as semiconductor chips or semiconductor dice). Each of the semiconductor chips may be mounted on a package substrate and may be encapsulated to form a semiconductor chip package. The package substrate may have interconnection lines including power lines supplying electric power to the semiconductor chip and signal lines transmitting data signals. The interconnection lines may be disposed in and/or on a core layer including a dielectric layer. The package substrate may be a printed circuit board (PCB).

### SUMMARY

Various embodiments are directed to package substrates and methods of fabricating the same.

According to some embodiments, a package substrate includes a core layer having a first surface defining trench portions and ridge portions between the trench portions, at least one first trace on a bottom surface of each of the trench portions, and second traces on respective ones of top surfaces of the ridge portions.

According to further embodiments, a package substrate includes a core layer having a surface defining trench portions and ridge portions between the trench portions; traces disposed on top surface of the ridge portions, bottom surface of the trench portions, or sidewalls of the ridge portions; and a protection layer filling the trench portions and covering the traces and the ridge portions.

According to still another embodiment, an electronic system includes a memory, and a controller coupled with the memory through a bus. The memory or controller may include a package substrate comprising a core layer having a surface defining trench portions and ridge portions between the trench portions; traces disposed on top surface of the ridge portions, bottom surface of the trench portions, or sidewalls of the ridge portions; and a protection layer filling the trench portions and covering the traces and the ridge portions; and a chip mounted on the package substrate.

In yet another embodiment, a memory card comprises a memory; and a memory controller controlling an operation of the memory. The memory may comprise a package substrate comprising a core layer having a surface defining trench portions and ridge portions between the trench portions; traces disposed on top surface of the ridge portions, bottom surface of the trench portions, or sidewalls of the ridge portions; and a protection layer filling the trench portions and covering the traces and the ridge portions; and a chip mounted on the package substrate.

According to further embodiments, a method of fabricating a package substrate includes forming ridge portions and trench portions in a core layer and forming traces on the core layer including the ridge portions and the trench portions.

### BRIEF DESCRIPTION OF THE DRAWINGS

Embodiments of the inventive concept will become more apparent in view of the attached drawings and accompanying detailed description, in which:

FIG. 1 is a perspective view illustrating an example embodiment of a package substrate and a chip mounted thereon according to some embodiments;

FIG. 2 is a plan view illustrating interconnection traces of a package substrate according to some embodiments;

FIG. 3 is a cross sectional view illustrating a package substrate according to some embodiments;

FIG. 4 is a cross sectional view illustrating a core layer of a package substrate according to some embodiments;

FIG. 5 is a perspective view illustrating interconnection traces of a package substrate according to some embodiments;

FIG. 6 is a perspective view illustrating interconnection traces of a package substrate according to a comparative example;

FIGS. 7 to 10 are cross sectional views illustrating a method of fabricating a package substrate according to some embodiments;

FIGS. 11 to 13 are cross sectional views illustrating package substrates according to some embodiments;

FIG. 14 is a block diagram illustrating an example of an electronic system including a semiconductor chip package in accordance with an embodiment of the inventive concept; and

FIG. 15 is a block diagram illustrating an example of an electronic system including a semiconductor chip package in accordance with an embodiment of the inventive concept.

### DETAILED DESCRIPTION OF THE EMBODIMENTS

It will be understood that although the terms first, second, third etc. may be used herein to describe various elements, these elements should not be limited by these terms. These terms are only used to distinguish one element from another element. Thus, a first element, which in some embodiments could also be termed a second element without departing from the teachings of the present invention.

It will also be understood that when an element is referred to as being “on”, “above”, “below”, or “under” another element, it can be directly “on”, “above”, “below”, or “under” the other element, respectively, or intervening elements may also be present. Accordingly, terms such as “on”, “above”, “below” or “under” which are used herein are used for the purpose of describing particular embodiments only, and are not intended to limit the inventive concept.

It will be further understood that when an element is referred to as being “connected” or “coupled” to another element, the element can be directly connected or coupled to the other element or intervening elements may be present. In contrast, when an element is referred to as being “directly connected” or “directly coupled” to another element, there are no intervening elements present between the element and the other element. Other words used to describe the relationship between elements or layers should be interpreted in a like fashion (e.g., “between” versus “directly between”, “adjacent” versus “directly adjacent”, “on” versus “directly on”).

The number of the semiconductor chips mounted on current package substrates is increasing, and a size of each semiconductor chip package is getting smaller. Further, the number of contact pads for connecting the semiconductor chip to the package substrate is increasing, and the number of traces constituting the interconnection lines is also increasing. Thus, the traces have been scaled down to reduce a pitch size thereof. That is, it may be difficult to obtain a sufficient space between the conductive traces due to shrinkage of the conductive traces. The conductive traces may include a metallic material such as a copper material. If the conductive traces are formed of a copper material and a space between the conductive traces is reduced, electrical shortages between the conductive traces may occur due to copper migration. The electrical shortages between the conductive traces may degrade the reliability characteristic of the package substrate. In addition, if a width of the conductive traces is reduced, a cross sectional area of the conductive traces used as the power lines may also decrease, which may degrade electrical characteristics of the package substrate or semiconductor chips mounted on the package substrate

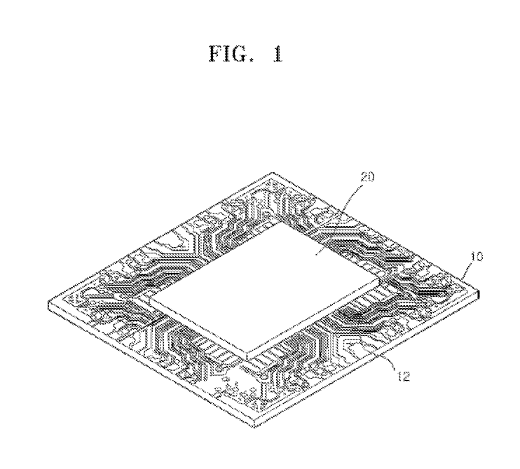

Referring to FIG. 1, a semiconductor package may include a package substrate 10 and a chip 20 mounted on the package substrate 10. The chip 20 may be a semiconductor chip in which integrated circuits are formed. For example, the chip 20 may be a memory chip such as a dynamic random access memory (DRAM) chip, a static random access memory (SRAM) chip, a flash memory chip, a magnetic random access memory (MRAM) chip, a resistive random access memory (ReRAM) chip, a ferroelectric random access memory (FeRAM) chip or a phase change random access memory (PCRAM) chip. Alternatively, the chip 20 may be a non memory chip such as a logic chip including logic circuits. The chip 20 may be construed as a semiconductor die or a semiconductor substrate in which integrated circuits are formed.

The package substrate 10 may include interconnection lines 12 constituting interconnection traces which are used in control operations of the chip 20. The interconnection lines 12, that is, the interconnection traces may include power lines supplying electric power to the chip 20 and signal lines transmitting data signals. The interconnection traces 12 may electrically connect the chip 20 to the package substrate 10. The chip 20 may be electrically connected to the interconnection traces 12 through bumps or bonding wires. The package substrate 10 may be a printed circuit board (PCB). In some embodiments, the package substrate 10 may be an embedded substrate or a flexible substrate.

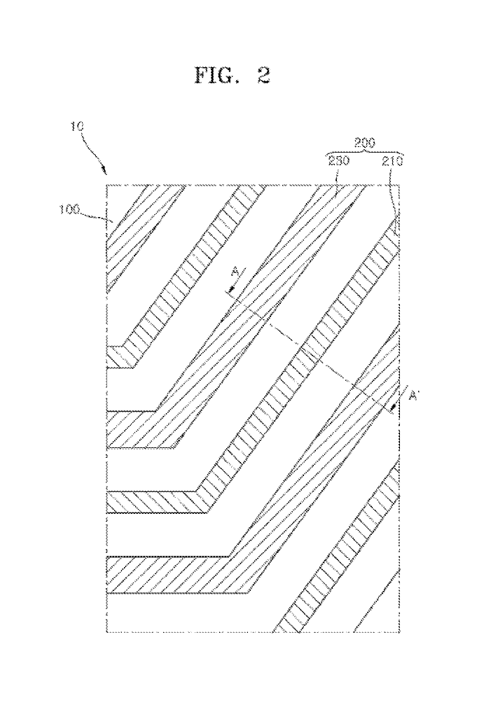

Referring to FIG. 2, interconnection traces 200 may be disposed in parallel on a core layer 100 to constitute an interconnection circuit. The interconnection traces 200 may include first traces 210 and second traces 230. The first traces 210 may act as signal lines through which data signals DQ0, DQ1, DQ2 . . . and DQn are transmitted between the chip 20 and the package substrate 10. The second traces 230 may act as power lines through which a power supply voltage VDD and a ground voltage VSS are supplied to the chip 20.

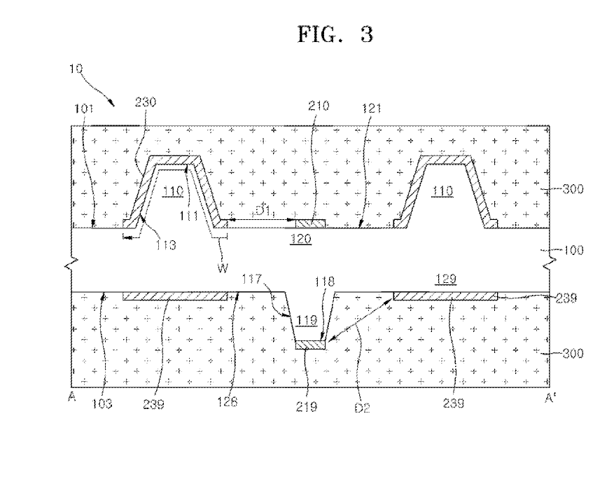

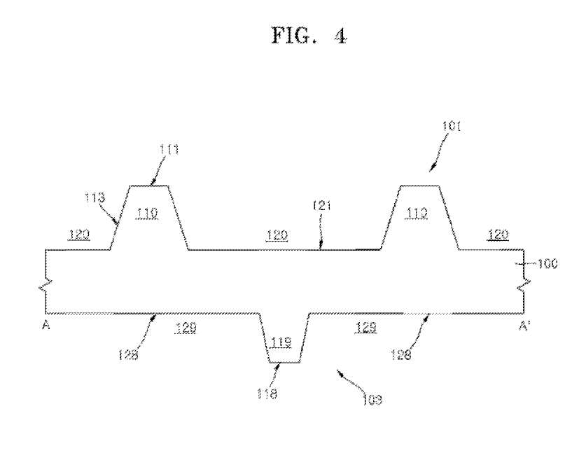

FIG. 3 is a cross sectional view taken along a line A-A′ of FIG. 2, and FIG. 4 is a cross sectional view of a core layer 100 shown in FIG. 3. Referring to FIGS. 3 and 4, the core layer 100 of the package substrate 10 may be a board-shaped dielectric layer and the core layer 100 may act as a body of the package substrate 10. Surfaces 101 and 103 of the core layer 100 may define trench portions 120 and 129 and ridge portions 110 and 119. The trench portions 120 and 129 may correspond to concave regions extending to have line shapes in a plan view, and the ridge portions 110 and 119 may correspond to protrusions which are relatively elevated between trench portions 120 and 129. The ridge portions 110 and 119 may also extend to have line shapes in a plan view. Further, from a plan view, the trench portions 120 and 129 and the ridge portions 110 and 119 may be disposed such that the trench portions 120 and 129 and the ridge portions 110 and 119 are substantially parallel.

First trench portions 120 and first ridge portions 110 may be disposed on a first surface 101 that may be a front surface of the core layer 100. Second trench portions 129 and second ridge portions 119 may be disposed on a second surface 103 that may be a back surface of the core layer 100 opposite to the first surface 101. The second ridge portions 119 may be located such that the second ridge portions 119 overlap with the first trench portions 120 when FIG. 3 is viewed from a plan view. The second trench portions 129 may be located such that the second trench portions 129 overlap with the first ridge portions 110 when FIG. 3 viewed from a plan view. Accordingly, the core layer 100 may have a uniform thickness. If the first trench portions 120 overlap with the second trench portions 129, the core layer 100 may be easily damaged or broken because of a non uniform thickness thereof. One of the first traces 210 may be disposed on a bottom surface of the first trench portion 120, and the second traces 230 may be disposed on top surfaces 111 of the first ridge portions 110. As described above, the first traces 210 may be signal lines, and the second traces 230 may be power lines. Each of the first and second traces 210 and 230 may be comprised of a conductive layer such as a copper layer. The first traces 210 may be disposed such that the first traces 210 do not fully cover the bottom surfaces 121 of the first trench portions 120. That is, each of the first traces 210 may be disposed to leave a portion of the bottom surface 121 exposed such that parts of the bottom surface 121 are not covered by the first traces 210.

The second traces 230 may fully cover the top surfaces 111 of the first ridge portions 110 and may extend to cover at least portions of the sidewalls 113 of the first ridge portions 110. In one embodiment, the second traces 230 may extend to fully cover one or more sidewalls 113 of the first ridge portions 110. Specifically, each of the second traces 230 may extend to cover at least one sidewall 113 of any one of the first ridge portions 110. Further, the second traces 230 may extend onto bottom surfaces 121 of the first trench portion 120. In still another embodiment, the second traces 230 extend onto opposite sidewalls (i.e., both sidewalls) of the ridge portions 110, 119. Thus, while the second traces 230 are disposed to be spaced apart from the first traces 210 by a distance D1, a line width W of the second traces 230 can be maximized because the second trace may extend onto at least one sidewall 113 and top surfaces 111 of the first ridge portions 110. In such a case, the line width W of the second traces 230 may be greater than a line width of the first traces 210. Although the present embodiment is described in conjunction with an example that the second traces 230 cover the sidewalls 113 of the first ridge portions 110, the inventive concept is not limited thereto. For example, in some embodiments, the second traces 230 may be disposed to cover only the top surfaces 111 of the first ridge portions 110, and the first traces 210 may fully cover the bottom surfaces 121 of the first trench portions 120 and may extend onto sidewalls 113 of the first ridge portion. That is, the first traces 210, in one embodiment may cover at least portions of the sidewalls 113 of the first ridge portions 110. In such a case, a width of the first traces 210 may be greater than that of the second traces 230. Thus, in some embodiments, the first traces 210 may be used as power lines and the second traces 230 may be used as signal lines.

Second bottom traces 219 may be disposed on top surfaces 118 of the second ridge portions 119. Further, first bottom traces 239 may be disposed on bottom surfaces 128 of the second trench portions 129. A width of the second bottom traces 219 may be less than that of the first bottom traces 239. Thus, the second bottom traces 219 may be used as signal lines, and the first bottom traces 239 may be used as power lines, such as power supply voltage lines and ground voltage lines. The first bottom traces 239 may be located at a different level than the second bottom traces 219, and the first bottom traces 239 may be spaced apart from the second bottom traces 219 by an effective distance D2. Even if a copper migration phenomenon of the first and second bottom traces 239 and 219 occurs, the probability of an electrical shortage between the adjacent bottom traces 239 and 219 may be significantly lowered, which improves the reliability of the package substrate 10.

Referring again to FIG. 3, the package substrate 10 may further include a protection layer 300 covering the traces 210, 230, 219 and 239, the ridge portions 110 and 119, and the core layer 100. The protection layer 300 may also fill the trench portions 120 and 129. The protection layer 300 may include a dielectric layer that electrically insulates and physically isolates the traces 210, 230, 219 and 239 from each other. For example, the protection layer 300 may include a solder resist layer. Each of the first traces 210 acting as signal lines may be disposed between a couple of adjacent second traces 230 acting as power lines. Each of the second bottom traces 219 may be disposed between a couple of adjacent first bottom traces 239. As a result, an interference phenomenon between two adjacent signal lines may be suppressed due to the presence of the power line disposed therebetween.

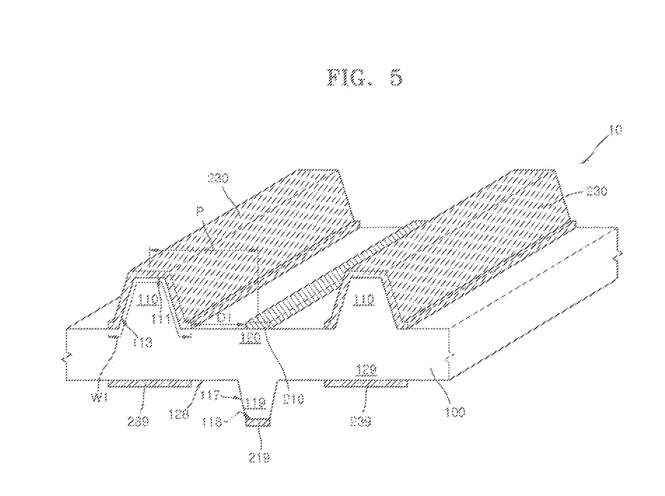

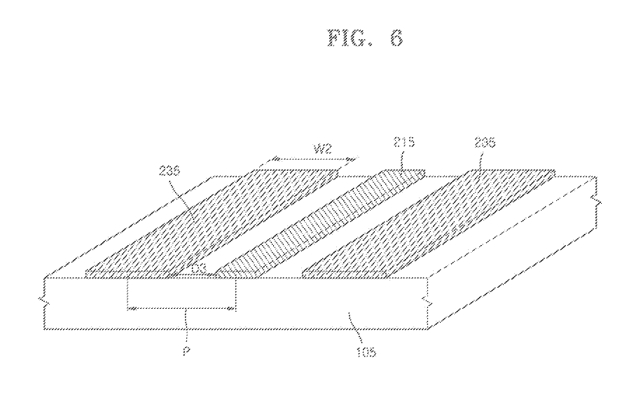

Referring to FIG. 5, the first trace 210 of the package substrate 10 according to some embodiments may be disposed in the trench portion 120 and the second traces 230 of the package substrate 10 according to some embodiments may be disposed to cover the ridge portions 110, as described with reference to FIG. 3. That is, the first trace 210 acting as a signal line may be disposed on the bottom surface of the trench portion 120, and each of the second traces 230 acting as a power line (i.e., a power supply voltage line or a ground voltage line) may be disposed on the top surface 111 and the sidewalls 113 of the ridge portion 110. In contrast, when a flat core layer 105 is employed in a package substrate as illustrated in FIG. 6, a third trace 215 acting as a signal line and fourth traces 235 acting as power lines may be disposed on a flat surface of the core layer 105. Thus, even though a pitch P of the first and second traces 210 and 230 shown in FIG. 5 is equal to a pitch P of the third and fourth traces 215 and 235 shown in FIG. 6 when viewed from a plan view, a distance D1 between the first and second traces 210 and 230 may be greater than a distance D3 between the third and fourth traces 215 and 235 even though an effective width W1 of the second traces 230 is equal to a width W2 of the fourth traces 235. The pitch P indicates a distance between central points of a pair of adjacent traces.

If the second traces 230 serve as power lines, second trace 230 may have a greater cross sectional area than each first trace 210. In the comparative example shown in FIG. 6, to increase a cross sectional area of each fourth trace 235 without increasing a thickness and a pitch of the fourth traces 235, a width of the fourth traces 235 should be increased. In such a case, however, the distance D3 between the third trace 215 and the fourth trace 235 may be reduced. Reduction of the distance D3 may increase a probability of electrical shortage between the third trace 215 and the fourth trace 235 due to a metal migration phenomenon between the third and fourth traces 215 and 235 when the third and fourth traces 215 and 235 are formed of metal such as a copper material. In contrast, even though the width of the second traces 230 shown in FIG. 5 increased, the reduced distance D1 between the first and second traces 210 and 230 may still be sufficient to prevent the electrical shortage between the first and second traces 210 and 230. This is because the original distance D1 between the first and second traces 210 and 230 is greater than the original distance D3 between the third and fourth traces 215 and 235.

As described above, the second traces 230 (acting as power lines) shown in FIG. 5 may be designed to have a greater width than the fourth traces 235 shown in FIG. 6 due to a step difference provided by the presence of the ridge portions 110 and the trench portions 120. In such a case, if the second traces 230 are used as power supply voltage lines and the first bottom traces 239 facing the second traces 230 are used as ground voltage lines, a coupling capacitance value between second traces 230 and the first bottom traces 239 may be increased. As a result, noise signals in the power supply voltage and the ground voltage may be easily filtered to provide a stable power supply voltage and a stable ground voltage.

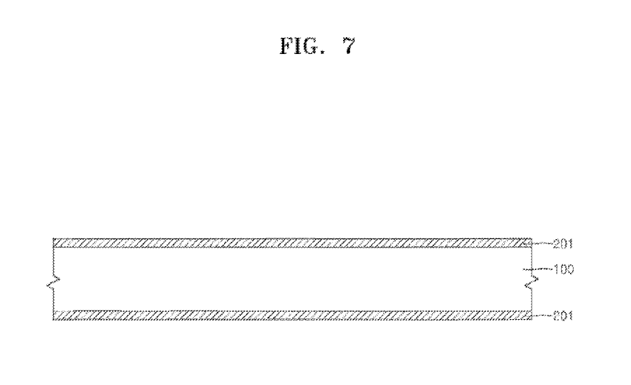

Hereinafter, a method of fabricating a package substrate according to some embodiments will be described with reference to FIGS. 7 to 10.

Referring to FIG. 7, a core layer 100 may be provided. The core layer 100 may be formed of a dielectric material having an insulating property. For example, the core layer 100 may be formed of a dielectric material including a glass fiber material and an epoxy resin material. Alternatively, the core layer 100 may be formed of a prepreg material. A conductive layer 201 such as a copper layer may be formed on the core layer 100. The conductive layer 201 may be formed using a lamination technique, and the core layer 100 and the conductive layer 201 may constitute a copper clad laminate (CCL) type substrate.

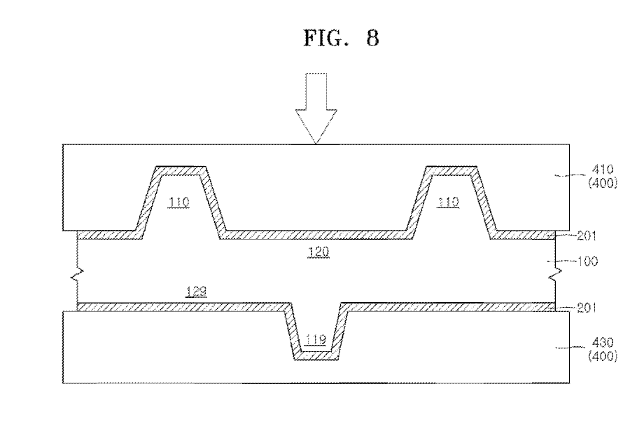

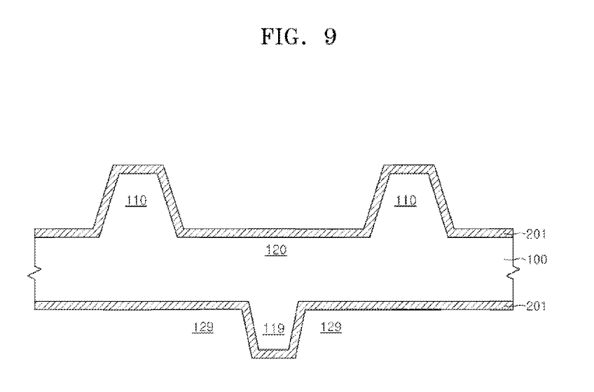

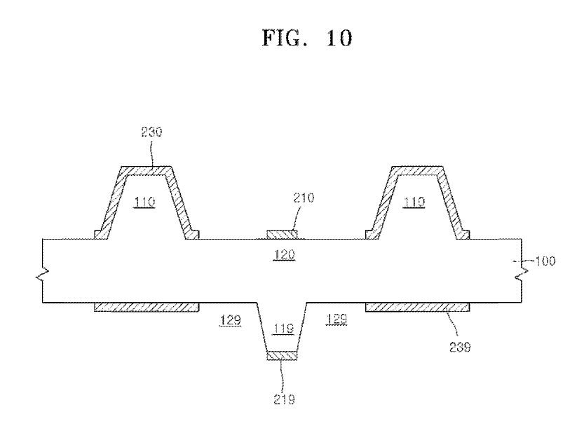

Referring to FIG. 8, a press process, for example, a molding process may be performed using a mold frame 400 to form ridge portions 110 and 119 and trench portions 120 and 129 (see, for example FIG. 10) at surfaces of the core layer 100 The mold frame 400 may include an upper mold frame 410 and a lower mold frame 430 that define shapes of the ridge portions 110 and 119 and trench portions 120 and 129. The press process may be performed by disposing the core layer 100 covered with the conductive layer 201 between the upper and lower mold frames 410 and 430 and by applying a press to the conductive layer 201 and the core layer 100 with mold frames 410 and 430. As a result, the ridge portions 110 and 119 and the trench portions 120 and 129 may be formed at surfaces of the core layer 100. The core layer 100 formed of a dielectric layer may have a semi-cured state. Thus, the core layer 100 may be deformed by the molding process to have the ridge portions 110 and 119 and the trench portions 120 and 129, and the deformed core layer 100 may be cured using a heating process to produce the ridge portions 110 and 119 and the trench portions 120 and 129 having solid states. During the molding process, the conductive layer 201 may also be deformed to have a profile which is consistent with a surface of the deformed core layer 100. As a result, the core layer 100 and the conductive layer 201 may be deformed by the molding process to have a rugged surface defining the ridge portions 110 and 119 and the trench portions 120 and 129, as illustrated in FIG. 9.

Subsequently, the molded conductive layer 201 may be patterned to form traces 210, 230, 219 and 239, as illustrated in FIG. 10. As described with reference to FIG. 3, the first trace 210 may be formed on a bottom surface of the first trench portion 120, the second traces 230 may be formed to cover the first ridge portions 110, the second bottom trace 219 may be formed on the second ridge portion 119, and the first bottom traces 239 may be formed on bottom surfaces of the second trench portions 129. Specifically, an etch mask pattern (not shown) may be formed on the conductive layer (201 of FIG. 9), and the conductive layer 201 may be etched using the etch mask pattern to form the traces 210, 230, 219 and 239. Alternatively, the traces 210, 230, 219 and 239 may be formed by forming a plating mask pattern (not shown) on the conductive layer 201, selectively forming an additional conductive layer on the conductive layer 201 not covered by the plating mask pattern, removing the plating mask pattern, and blanket etching the conductive layer including the additional conductive layer until the initial conductive layer 201 is removed. The plating mask pattern may have a reverse pattern of the etch mask pattern.

After the traces 210, 230, 219 and 239 are formed, a protection layer 300 may be formed to cover the traces 210, 230, 219 and 239 and the core layer 100 (see, for example, FIG. 3). The protection layer 300 may be formed of a dielectric layer, for example, a solder resist layer, and the traces 210, 230, 219 and 239 may be insulated from each other by the protection layer 300.

In some embodiments, the ridge portions 110 and 119, and the trench portions 120 and 129 may be formed using a selective etch process without use of the mold process. Specifically, portions of the core layer 100 may be selectively etched to form the trench portions 120 and 129 in the core layer 100, as illustrated in FIG. 4. The trench portions 120 and 129 may include the ridge portions 110 and 119 disposed therebetween. A conductive layer, such as conductive layer 201, may be formed on top and bottom surfaces of the core layer 100 including the ridge portions 110 and 119 and the trench portions 120 and 129, and the conductive layer 201 may be patterned using a selective etch process or a selective plating process to form traces 210, 230, 219 and 239.

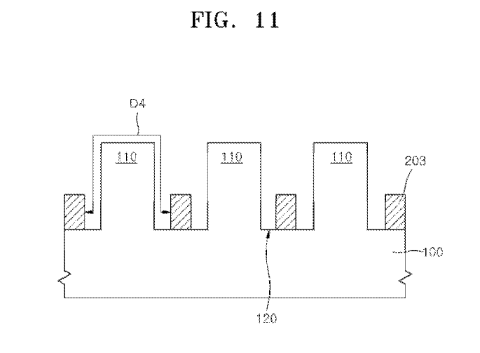

Referring to FIG. 11, a core layer 100 of a package substrate according to some embodiments may include an uneven surface defining ridge portions 110 and trench portions 120 which are alternately and repeatedly arrayed. Traces 203, that is, interconnection traces may be disposed between the trench portions 120. The traces 203 may be formed on bottom surfaces of the trench portions 120. In some embodiments, the traces 203 may extend to cover sidewalls of the trench portions. That is, in some embodiments, the traces 203 do not extend onto top surfaces of the ridge portions 110. As a result, at least top surfaces of the ridge portions 110 may be exposed by the traces 203.

Each of the ridge portions 110 may be disposed between two adjacent traces 203. Thus, an effective distance D4 along a surface of the core layer 100 between the adjacent traces 203 may be greater than a direct distance between the adjacent traces 203. As a result, even though the traces 203 are formed of a copper layer and a copper migration phenomenon occurs, electrical shortage between the traces 203 may be prevented. Further, even though a thickness of the traces 203 increases, a probability of the electrical shortage between the traces 203 due to the electro-migration may still be lowered. Increase of the thickness of the traces 203 may reduce electrical resistance of the traces 203. Accordingly, if the traces 203 are used as power lines, a stable power supply voltage may be transmitted through the traces 203. Similarly, if the traces 203 are used as signal lines, data signals may be stably transmitted through the traces 203 without severe attenuation of the data signals.

Referring to FIG. 12, a core layer 100 of a package substrate according to some embodiments may also include an uneven surface defining ridge portions 110 and trench portions 120 which are alternately and repeatedly arrayed. Each of the ridge portions 110 may include a first side wall and a second sidewall opposite to the first sidewall. The first sidewalls 114 of the ridge portions 110 may be covered with traces 205. In some embodiments, the traces 205 may extend onto top surfaces of the ridge portions 110 and/or bottom surfaces of the trench portions 120. However, the traces 205 do not extend onto second sidewalls 115 of the ridge portions 110 opposite to the first sidewalls 114. That is, the second sidewalls 115 of the ridge portions 110 may remain uncovered by the traces 205. Each of the second sidewalls 115 may be disposed between two adjacent traces 205 which are spaced apart from each other by a direct distance D5. Thus, if a height of the ridge portions 110 increases, a height of the second sidewalls 115 also increases to thus increase an effective distance between the traces 205 without the increasing a planar area of the core layer 100.

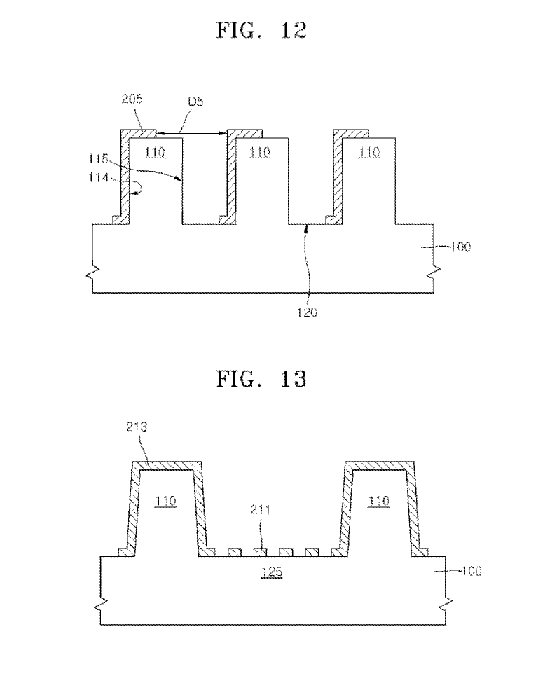

Referring to FIG. 13, a core layer 100 of a package substrate according to some embodiments may include a pair of ridge portions 110 and a trench portion 125, where the trench portion 125 may be disposed between the pair of ridge portions 110. Second traces 213 acting as power lines may be disposed to cover respective ones of the ridge portions 110, and a plurality of first traces 211 may be disposed on a bottom surface of the trench portion 125. Thus, in one embodiment, the conductive layer 201 may be etched such that each of the second traces 213 extends to cover opposite sidewalls of each of the ridge portions 210. In another embodiment, the conductive layer 201 may be etched such that each of the second traces 213 extends to cover one of the opposite sidewalls of each of the ridge portions 110. Thus, a width of the trench portion 125 may be greater than that of each individual ridge portion 110. Each of the first traces 211 acting as signal lines may have a width which is less than that of each of the second traces 213 acting as power lines. Accordingly, the ridge portions 110 may be selectively disposed under respective ones of the second traces 213 to increase a width of the second traces 213.

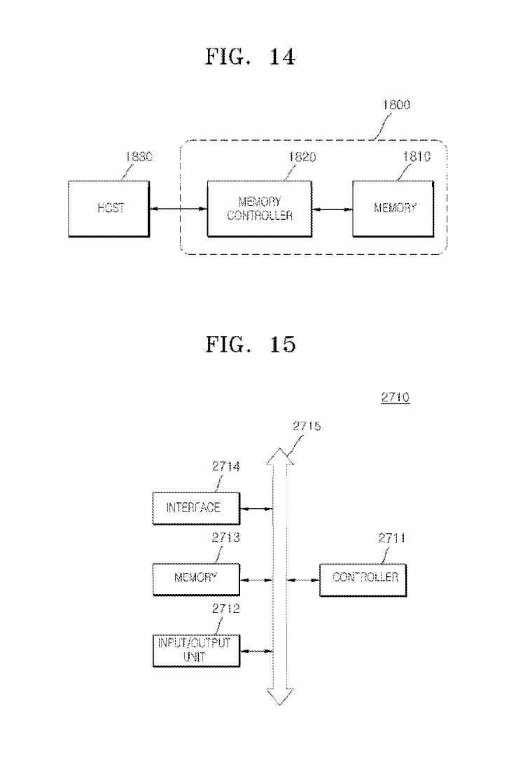

Referring to FIG. 14, the package substrate in accordance with the embodiments may be adopted to form semiconductor chip package in the form of a memory card 1800. For example, the memory card 1800 may include a memory 1810 such as a nonvolatile memory device and a memory controller 1820. The memory 1810 and the memory controller 1820 may store data or read stored data.

The memory 1810 may include at least any one among nonvolatile memory devices to which the packaging technology of the embodiments of the present invention is applied. The memory controller 1820 may control the memory 1810 such that stored data is read out or data is stored in response to a read/write request from a host 1830.

Referring to FIG. 15, the package substrate in accordance with embodiments disclosed herein may be adopted to form a semiconductor chip package which may be applied to an electronic system 2710. The electronic system 2710 may include a controller 2711, an input/output unit 2712, and a memory 2713. The controller 2711, the input/output unit 2712 and the memory 2713 may be coupled with one another through a bus 2715 providing a path through which data move.

For example, the controller 2711 may include at least any one of at least one microprocessor, at least one digital signal processor, at least one microcontroller, and logic devices capable of performing the same functions as these components. The controller 2711 and the memory 2713 may include at least any one of the flexible stack packages according to the embodiments of the present invention. The input/output unit 2712 may include at least one selected among a keypad, a keyboard, a display device, a touch screen and so forth. The memory 2713 is a device for storing data. The memory 2713 may store data and/or commands to be executed by the controller 2711, and the likes.

The memory 2713 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this case, the electronic system 2710 may stably store a large amount of data in a flash memory system.

The electronic system 2710 may further include an interface 2714 configured to transmit and receive data to and from a communication network. The interface 2714 may be a wired or wireless type. For example, the interface 2714 may include an antenna or a wired or wireless transceiver.

The electronic system 2710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

In the case where the electronic system 2710 is an equipment capable of performing wireless communication, the electronic system 2710 may be used in a communication system such as of CDMA (code division multiple access), GSM (global system for mobile communications), NADC (north American digital cellular), E-TDMA (enhanced-time division multiple access), WCDAM (wideband code division multiple access), CDMA2000, LTE (long term evolution), Wibro (wireless broadband Internet), etc.

The embodiments of the inventive concept have been disclosed above for illustrative purposes. Those skilled in the art will appreciate that various modifications, additions and substitutions are possible, without departing from the scope and spirit of the inventive concept as disclosed in the accompanying claims.

What is claimed is:

1. A package substrate comprising:
a core layer having a first surface defining trench portions and ridge portions between the trench portions;
a first trace on a bottom surface of the trench portion; and
a second trace on respective ones of top surfaces of the ridge portions.

2. The package substrate of claim 1, wherein the first trace extends onto sidewalls of the ridge portions.

3. The package substrate of claim 1, wherein the second trace extends to cover at least one sidewall of one of the ridge portions.

4. The package substrate of claim 3, wherein the second trace extends onto bottom surfaces of the trench portions.

5. The package substrate of claim 1, wherein the second trace extends onto opposite sidewalls of the ridge portion.

6. The package substrate of claim 1, wherein the second trace has a different width than the first trace.

7. The package substrate of claim 1:
wherein the second trace acts as power line where a power line includes at least one of a power supply voltage line or at least one of a ground voltage line; and
wherein the first trace acts as signal line.

8. The package substrate of claim 7, the first trace is disposed between two adjacent ones of the second traces.

9. The package substrate of claim 1, wherein the trench portion and the ridge portion are disposed to be parallel with each other.

10. The package substrate of claim 1, further comprising a protection layer covering the first and second trace and the core layer.

11. The package substrate of claim 1, wherein the core layer further includes a second ridge portion disposed on a second surface of the core layer opposite to the first surface to overlap with the trench portion in a plan view and a second trench portion disposed between the second ridge portions to overlap with the ridge portion in the plan view, the package substrate further comprising:
a first bottom trace disposed on bottom surface of the second trench portion; and
a second bottom trace disposed on top surface of the second ridge portion.

12. A package substrate comprising:
a core layer having a surface defining trench portions and ridge portions between the trench portions;
traces disposed on a top surface of the ridge portions, a bottom surface of the trench portions, or sidewalls of the ridge portions; and
a protection layer filling the trench portions and covering the traces and the ridge portions.

13. The package substrate of claim 12:
wherein each of the ridge portions has a first sidewall and a second sidewall opposite to the first sidewall;
wherein one of the traces is disposed on the top surface of the ridge portion and is expanded to cover the first and second sidewalls of the ridge portion; and
wherein others of the traces are disposed on the bottom surface of the trench portion.

14. The package substrate of claim 12:
wherein each of the ridge portions has a first sidewall and a second sidewall opposite to the first sidewall;
wherein the traces are disposed on respective ones of the first sidewalls of the ridge portions; and
wherein the second sidewalls of the ridge portions are exposed by the traces.

15. A method of fabricating a package substrate, the method comprising:
forming ridge portions and trench portions in a core layer; and
forming traces on the core layer including the ridge portions and the trench portions.

16. The method of claim 15, wherein forming the ridge portions and the trench portions includes:
forming a conductive layer on the core layer; and
applying a press to the conductive layer and the core layer with a molding frame having shapes of the ridge portions and the trench portions.

17. The method of claim 16, wherein forming the traces includes etching the conductive layer to form first traces disposed on bottom surfaces of the trench portions and second traces disposed on top surfaces of the ridge portions.

18. The method of claim 17, wherein the conductive layer is etched such that each of the second traces extends to cover one of opposite sidewalls of each of the ridge portions.

19. The method of claim 17, wherein the conductive layer is etched such that each of the second traces extends to cover opposite sidewalls of each of the ridge portions.

20. The method of claim 15, further comprising forming a protection layer covering the traces and the core layer.
